(19) United States
(12) Patent Application Publication
(10) Pub. No.: US 2024/0142490 A1
(43) Pub. Date: May 2, 2024

(54) MICROMECHANICAL SENSOR WITH INTEGRATED STRESS SENSOR AND METHOD FOR THE SIGNAL CORRECTION OF A SENSOR SIGNAL

(71) Applicant: Robert Bosch GmbH, Stuttgart (DE)

(72) Inventor: Johannes Classen, Reutlingen (DE)

(21) Appl. No.: 18/483,784

(22) Filed: Oct. 10, 2023

(30) Foreign Application Priority Data
Oct. 31, 2022 (DE) 10 2022 211 541.4

(51) Int. Cl. G01P 15/125; B81B 7/00; B81C 1/00

(52) U.S. Cl. CPC G01P 15/125; B81B 7/008; B81C 1/00238; B81B 2201/0235

(57) ABSTRACT

A micromechanical sensor. The micromechanical sensor includes a MEMS substrate, on which a micromechanical structure including at least one sensor electrode is disposed in a cavity, and including a cap substrate, which is disposed over the micromechanical structure and closes the cavity. A capacitive electrode, which produces a measuring capacitance with an adjacent micromechanical structural element on the MEMS substrate for measuring a distance between the capacitive electrode and the micromechanical structural element, is disposed on an inner side of the cap substrate. A method for the signal correction of a sensor signal of such a micromechanical sensor is also described.

### CROSS REFERENCE

The present application claims the benefit under 35 U.S.C. § 119 of German Patent Application No. DE 10 2022 211 541.4 filed on Oct. 31, 2022, which is expressly incorporated herein by reference in its entirety.

### FIELD

The present invention relates to a micromechanical sensor comprising a MEMS substrate, on which a micromechanical structure comprising at least one sensor electrode is disposed in a cavity, and comprising a cap substrate, which is disposed over the micromechanical structure and closes the cavity.

### BACKGROUND INFORMATION

Micromechanical inertial sensors for measuring acceleration and rotation rate are mass-produced for various applications in the automotive and consumer sectors. For capacitive acceleration sensors with a detection direction perpendicular to the wafer plane (z-direction), RB preferably uses “rockers”. The sensor principle of these rockers is based on a spring-mass system, in which, in the simplest case, a movable seismic mass with two counter electrodes fixed on the substrate forms two plate capacitors. The seismic mass is connected to the substrate via at least one, for symmetry reasons usually two, torsion springs. If the mass structures on the two sides of the torsion spring are of different sizes, the mass structure will rotate relative to the torsion spring as an axis of rotation under the effect of a z-acceleration. The distance between the electrodes thus becomes smaller on the side with the greater mass and greater on the other side. The change in capacitance is a measure of the acting acceleration. These acceleration sensors are described in numerous publications, for example, in European Patent Nos. EP 0 244 581 and EP 0 773 443 B1.

Trends in the further development of z-acceleration sensors include improving performance (in particular reduction of offset and noise) and continuous miniaturization to reduce costs and for use in new applications with severe installation space limitations such as wearables, hearables, smart glasses or smart contact lenses.

More modern z-sensor designs and associated technologies with a total of three silicon layers, such as those described in German Patent Application No. DE 10 2009 000 167 A1, for instance, are an important contribution to improving the performance of acceleration sensors, in particular in terms of offset and noise. Such a design results in lower offset and sensitivity drifts when bending stress occurs, for example due to circuit board bending or thermomechanical stress.

This compact z-acceleration sensor can be used for further miniaturization in so-called hybrid or vertical integration. A CMOS ASIC is used as a cap wafer for the MEMS wafer, and electrical contacts are also established between the MEMS functional elements and the ASIC in addition to a bond frame to hermetically seal the MEMS structures. Examples of vertical integration methods are described, among others, in U.S. Pat. Nos. 7,250,353 B2 and 7,442,570 B2, U.S. Patent Application Publication Nos. US 2010/0109102 A1, US 2011/0049652 A1, US 2011/0012247 A1, and US 2012/0049299 A1, and German Patent No. DE 10 2007 048 604 A1.

These vertically integrated wafer stacks can then be further processed into so-called chip scale packages (CSP), in which any substrates, glue, bonding wires, molding compounds, etc. are unnecessary and unpackaged silicon chips (“bare dies”) are mounted directly onto the application circuit board. The external electrical contacts of the ASIC are fed outward by means of through-silicon vias to the rear side of the ASIC, where they can be routed through a redistribution layer (RDL) and contacted by means of solder beads on an application circuit board. FIG. 3 shows this configuration as further prior art (the figure substantially corresponds to FIG. 6 of German Patent Application No. DE 10 2016 207 650 A1).

The use of the uppermost metal layer of the CMOS ASIC for additional evaluation electrodes for a z-acceleration sensor is described in German Patent Application Nos. DE 10 2012 208 032 A1 and DE 10 2015 217 921 A1.

### SUMMARY

An object of the present invention is to provide a micromechanical sensor which is as compact as possible and enables the measurement and compensation of mechanical stress effects on the micromechanical structures as well as an associated method for the signal correction of a sensor signal.

The present invention relates to a micromechanical sensor comprising a MEMS substrate, on which a micromechanical structure comprising at least one sensor electrode is disposed in a cavity, and comprising a cap substrate, which is disposed over the micromechanical structure and closes the cavity.

According to an example embodiment of the present invention, a capacitive electrode, which produces a measuring capacitance with an adjacent micromechanical structural element on the MEMS substrate for measuring a distance between the capacitive electrode and the micromechanical structural element, is disposed on an inner side of the cap substrate.

The micromechanical sensor according to an example embodiment of the present invention allows the measurement and compensation of mechanical stress within the device, preferably within a vertically integrated inertial sensor, such as in particular a z-acceleration sensor, wherein, in contrast to the prior art, no additional area is required in the sensor core for the arrangement for the stress measurement. Measuring the mechanical stress makes it possible to compensate stress-related sensitivity and offset errors of the acceleration sensor.

The use of additional electrodes in a metal layer close to the surface of the CMOS ASIC, which are positioned on the MEMS wafer opposite to a fixed structure, while the evaluation electrodes for the inertial sensor are disposed on the MEMS wafer, is advantageous. The placement of the additional electrodes above the fixed top electrodes of a z-acceleration sensor is proposed as a particularly preferred arrangement, because these areas are comparatively large and therefore a large capacitance with high measurement sensitivity can be provided. The z-acceleration sensor has a basic topology according to FIGS. 1, 2. The additional electrodes create capacitances to the top electrodes, which can be evaluated individually, summed or differentially.

On the ASIC side, the uppermost or the second uppermost metal layer is advantageously used, because it has the smallest distance to the upper side of the MEMS structure and therefore shows the greatest changes in capacitance when the distance changes. When mechanical stress occurs with components perpendicular to the chip plane, which is generally dominant in particular when the circuit board bends, changes in the distance between the fixed top electrodes and the additional electrodes will occur, which can be recorded by measuring the capacitance C_{1,top} and C_{2,top}. The capacitances C_{1,top} and C_{2,top}, on the other hand, do not change when accelerations occur. Inferences about the contribution of mechanical stress to the acceleration sensor signal can thus be drawn, and the respective contributions can be subtracted from the acceleration signal to ensure smaller offset and sensitivity errors. The arrangement advantageously does not require any additional area in the chip, because the area above the top electrodes would otherwise be unused.

The present invention also relates to a method for the signal correction of a sensor signal of a micromechanical sensor comprising a MEMS substrate, on which a micromechanical structure comprising at least one sensor electrode is disposed in a cavity, and comprising a cap substrate, which is disposed over the micromechanical structure and closes the cavity. The method according to an example embodiment of the present invention includes that the sensor signal is corrected by means of a capacitive electrode which produces a measuring capacitance with an adjacent micromechanical structural element on the MEMS substrate for measuring a distance between the capacitive electrode and the micromechanical structural element and is disposed on an inner side of the cap substrate, wherein the sensor signal is ascertained at least in part from a sensor capacitance between the sensor electrode and another part of the micromechanical structure.

The method according to the present invention makes it possible to measure deformations of the sensor and correct the effects of the deformations on the sensor signal.

Advantageous embodiments of the method are disclosed herein.

### BRIEF DESCRIPTION OF THE DRAWINGS

FIG. 1 schematically shows a prior art z-acceleration sensor in a cavalier perspective.

FIG. 2 shows the prior art z-acceleration sensor in the section AB of FIG. 1.

FIG. 3 schematically shows a prior art z-acceleration sensor with a semiconductor substrate as a cap.

FIG. 4 shows a micromechanical sensor according to the present invention in a first embodiment example.

FIG. 5 shows a compensation method for correcting a signal for a micromechanical sensor according to FIG. 4, according to an example embodiment of the present invention.

FIG. 6 shows the correlation of the measuring capacitance of a micromechanical sensor according to FIG. 4 to its sensor signal.

FIG. 7 shows a micromechanical sensor according to the present invention in a second embodiment example.

FIG. 8 shows a compensation method for correcting a signal for a micromechanical sensor according to FIG. 7, according to an example embodiment of the present invention.

FIG. 9 shows a micromechanical sensor according to the present invention in a third embodiment example.

### DETAILED DESCRIPTION OF EXAMPLE EMBODIMENTS

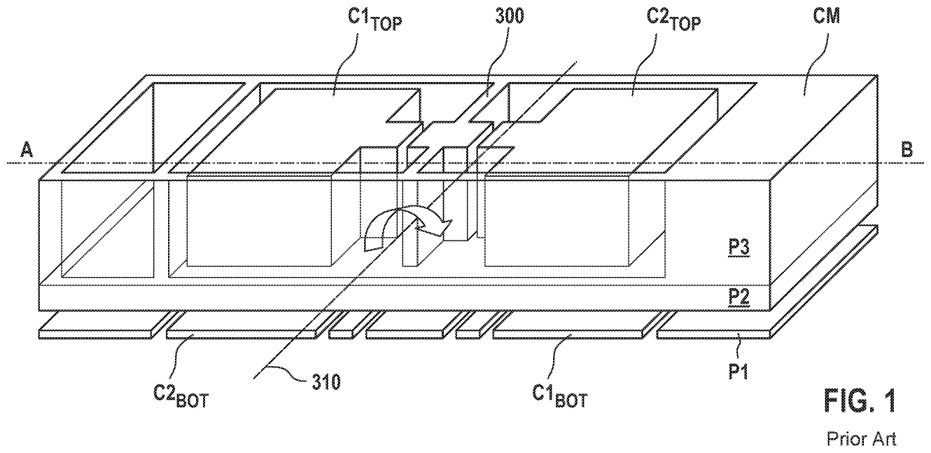

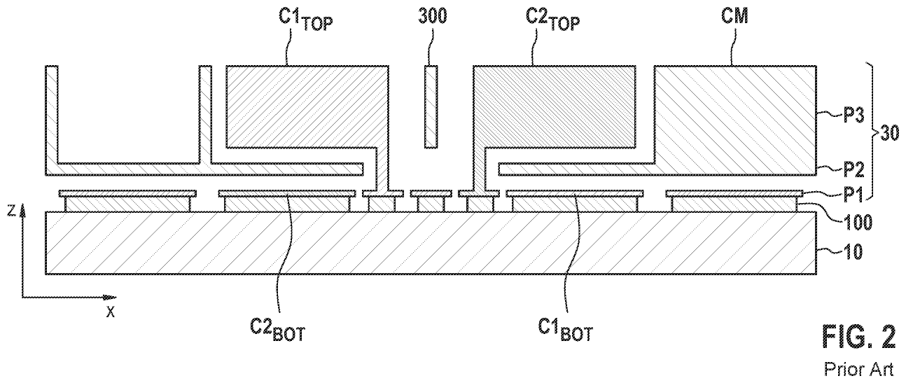

FIG. 1 schematically shows a prior art z-acceleration sensor in a cavalier perspective. FIG. 2 shows the section AB of FIG. 1. An oxide layer 100 is first disposed over a substrate 10. The micromechanical structure 30 of this z-sensor is made of three polysilicon layers P1, P2, P3, wherein the P1 layer is used for wiring, the P2 layer is used for a part of the movable structure and the P3 layer is used for a further part of the movable structure as well as for the implementation of top electrodes.

This sensor topology exhibits significant advantages over older rocker designs that were made of only one silicon functional layer and one wiring layer. Said advantages in particular include increased capacitance density (i.e. capacitance/area), because bottom electrodes (C1_{BOT} and C2_{BOT} in the P1 layer) and top electrodes (C1_{TOP} and C2_{TOP} in the P3 layer) are used, which results in an improved signal-to-noise ratio with the same sensor area (or a reduced sensor area with the same noise performance). The capacitances are typically evaluated differentially according to dC=(C1_{TOP}+C1_{BOT})−(C2_{TOP}+C2_{BOT}); therefore both the bottom and the top electrodes contribute to the signal.

The arrangement of sensor electrodes in the form of bottom and top electrodes moreover results in a lower susceptibility to bending stress, because the top electrodes are centrally suspended and the bottom electrodes can be made somewhat more compact (due to the additional capacitance produced by the top electrodes). The sensor electrodes are anchored to the MEMS substrate 10.

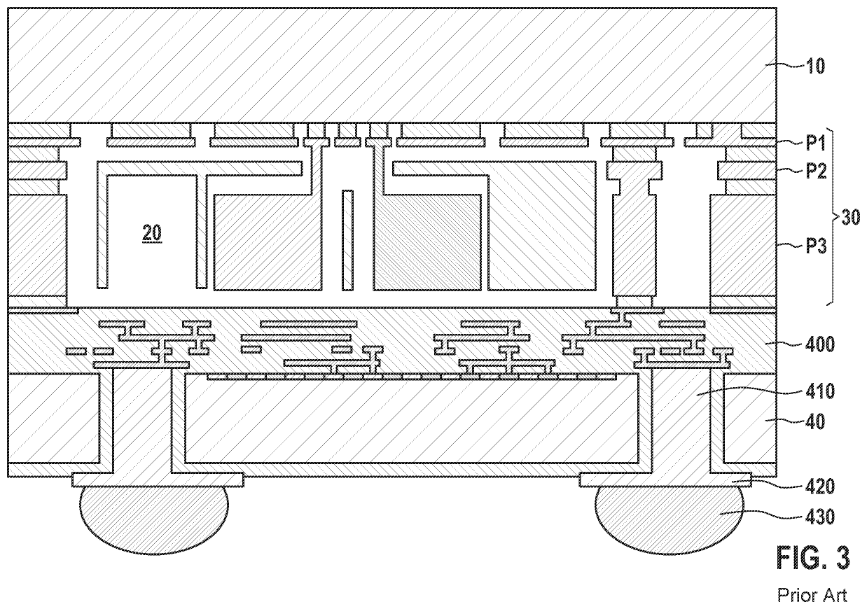

FIG. 3 schematically shows a prior art z-acceleration sensor with a semiconductor substrate as a cap. The figure shows a micromechanical device comprising a MEMS substrate 10, on which a micromechanical structure 30 is disposed in a cavity 20, and comprising a cap substrate 40, which is disposed over the micromechanical structure and closes the cavity.

The cap substrate is a semiconductor substrate with an integrated circuit (IC), namely an ASIC with CMOS layers 400. The external electrical contacts of the ASIC are fed outward by means of through-silicon vias 410 (TSV) to the rear side of the ASIC, where they can be routed through a redistribution layer 420 (RDL) and contacted by means of solder beads 430 on an application circuit board.

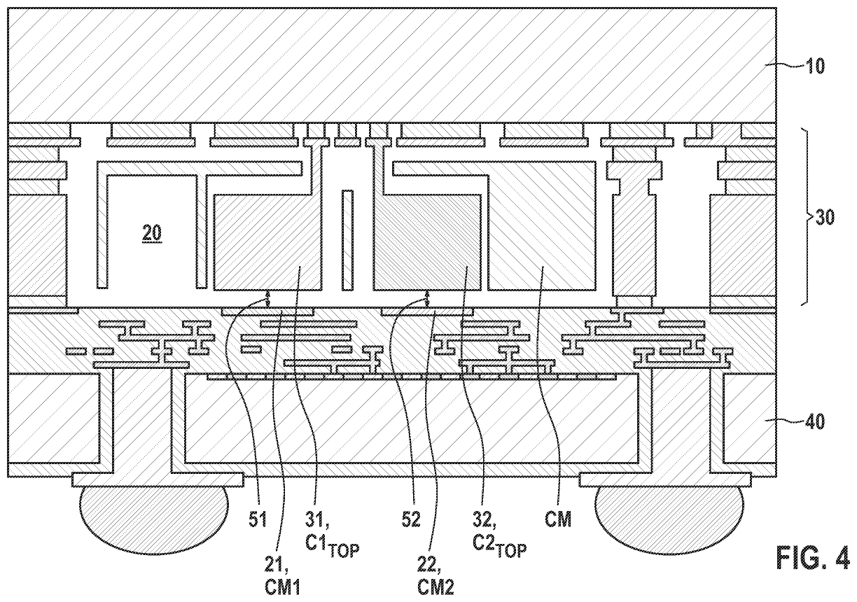

FIG. 4 shows a micromechanical sensor according to the present invention in a first embodiment example.

It corresponds to the device in FIG. 3 with the difference that a capacitive electrode 21, which produces a measuring capacitance with an adjacent micromechanical structural element 31 on the MEMS substrate for measuring a distance 51 between the capacitive electrode and the micromechanical structural element, is disposed on an inner side of the cap substrate 40. A further capacitive electrode 22, which produces a further measuring capacitance with a further adjacent micromechanical structural element 32 for measuring a further distance 52 between the further capacitive electrode and the further micromechanical structural element, is additionally disposed on the inner side of the cap substrate.

For this purpose, two additional electrodes, which are also referred to as CM1 and CM2 and are positioned opposite to the surfaces of sensor electrodes configured as the top electrodes C1_{TOP} and C2_{TOP} of the z-acceleration sensor, are disposed on the ASIC surface, in this case in the uppermost metal layer. The electrode CM1 produces a first additional capacitance CM1/C1_{TOP}, hereinafter referred to simply as C_{Z1}, with the surface of the electrode C1_{TOP}, and the electrode CM2 correspondingly produces a second additional capacitance CM2/C2_{TOP}, hereinafter referred to simply as C_{Z2}, with the surface of the electrode C2_{TOP}. Changes in the distance between the micromechanical structural elements 31, 32, namely the top electrodes, and the additional electrodes 21, 22, which can be induced in particular by mechanical stress, lead to changes in the capacitances which can be measured by a front-end ASIC with high resolution.

Since mechanical stress usually does not change abruptly in practice, the measurement of the additional capacitances can be heavily averaged over time in order to obtain a particularly low-noise signal. The additional electrodes CM1 and CM2 are galvanically isolated from one another and from the potential CM of the movable structure, so that a signal evaluation that is completely independent of the signal of the z-acceleration sensor is possible. The evaluation of the additional capacitances can thus be carried out by means of separate front-end ASICs or by switching (multiplexing) a single front end.

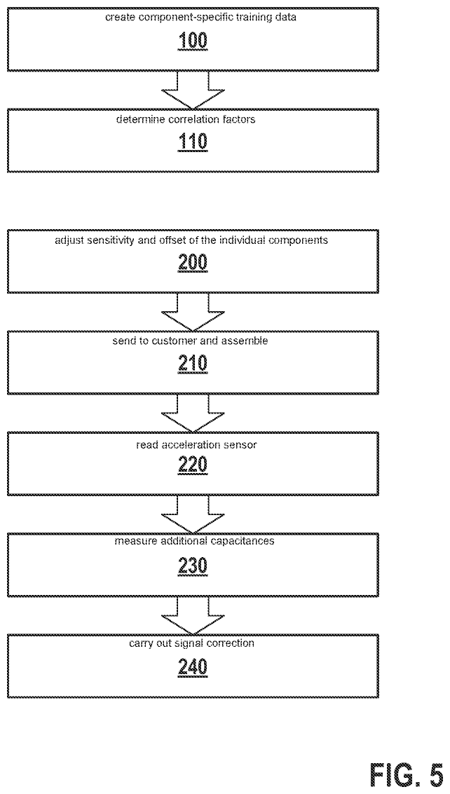

FIG. 5 shows a compensation method for correcting a signal for a micromechanical sensor according to FIG. 4.

The basic procedure of how the additional electrodes or additional capacitances can be used in practice is described. In a first step 100, component-specific training data have to be created. A defined ensemble of sensors is used for this purpose, for example a few hundred or a few thousand components which are soldered onto a circuit board specially prepared for bending tests. On the one hand, the signal from the acceleration sensor dC(σ, T) is read out with these sensors when the external mechanical stress varies. Apart from gravitational acceleration, there is no acceleration in this test step. On the other hand, the changes in the additional capacitances C_{Z1}(σ, T) and C_{Z2}(σ, T) are ascertained.

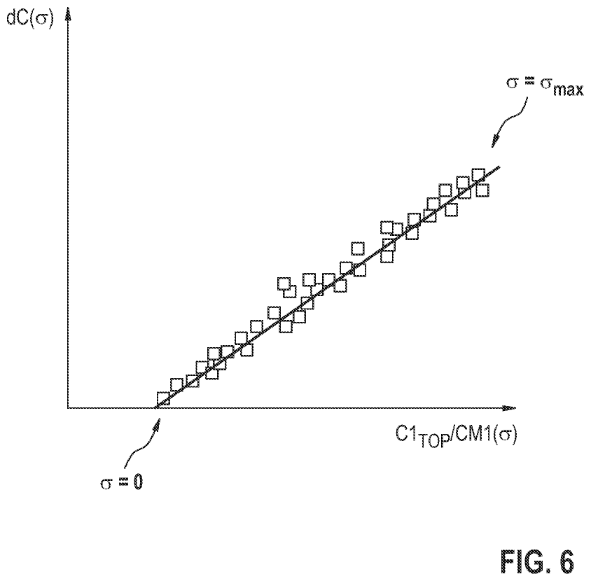

FIG. 6 shows the correlation of the measuring capacitance of a micromechanical sensor according to FIG. 4 to its sensor signal.

If the stress-dependent acceleration sensor data are plotted against the stress-dependent data of the additional capacitances, as shown schematically in FIG. 6 for the additional capacitance C_{Z1}, type-specific correlations, i.e. correlations that depend on the geometric relationships of the component, will emerge, which in the simplest case can be described with correlation factors V1 and V2. This takes place in a step 110. It should be noted that the correlation factors V1, V2 cannot necessarily be read directly from the straight line slopes according to FIG. 6, but have to rather be ascertained in a multidimensional optimization method in which both additional capacitances C_{Z1} and C_{Z2} are suitably correlated with the acceleration sensor signal. The difference C_{Z1}−C_{Z2} can also be included in the correction algorithm. It is also possible that non-linear terms, i.e. higher-order correction terms containing the measuring capacitance C_{Z1}, C_{Z2} or the difference C_{Z1}−C_{Z2} in quadratic, cubic or higher order, are ascertained for these correlations and later taken into account for the signal correction. This also makes it possible to identify more complex relationships between the sensor signal and the additional capacitances C_{Z1}, C_{Z2}. This enables an even more precise correction of the sensor signal using the additional capacitances C_{Z1}, C_{Z2}.

In the simplest case, only the correlation factors V1, V2 are derived, which represent an ensemble average (step 110). Strong component-individual scatter cannot be corrected with the ensemble approach, because only the ensemble average is included in the correlation factors in this simple case. In one embodiment of the method, however, it is also possible that additional sensor parameters such as layer thicknesses, lateral or vertical distances between the MEMS structural elements, or even data of the assembly and connection technique, which are known from the production data, for example, be taken into account when creating the correlations and enable further refinement of the correction procedure. For the sake of simplicity, however, a more detailed presentation of these methods which are possible and conceptually included in the present invention is omitted.

The measurement of the stress dependence within the ensemble can in principle also be carried out at many different temperatures T. Or only the temperature can be changed without applying variable mechanical stress. Both methods can also be used to ascertain temperature-dependent stress contributions, i.e. signal changes caused by thermomechanical stress due to different thermal expansion coefficients. The correlation factors can therefore also have a temperature dependence V1(T) and V2(T), which can be determined as an average value for the ensemble in order to also carry out a temperature-specific compensation of the acceleration sensor signal. The evaluation ASICs typically comprise integrated temperature sensors so that, if the temperature dependence of the correlation factors V1(T), V2(T) is known, a signal correction can be carried out not only at one temperature, but at any operating temperature.

The method steps 100, 110 described so far were carried out at the ensemble level. Ideally, ensemble training data only have to be created once before the start of production of a new sensor and can then be used for all individual components during subsequent high-volume production.

The following method steps 200-240, on the other hand, take place at the individual component level, i.e. apply to each individual component used by the end customer. In a step 200, the sensitivity and offset of the individual components are adjusted in accordance with the prior art. The individual components are then sent to the customer and assembled in the customer's application (210), typically by soldering them onto a circuit board of a terminal device, e.g. a smartphone or wearable. The acceleration sensor is read when the terminal device is in operation (220). In addition to the actually to be measured acceleration a, the evaluated signal dC(a, σ, T) will also contain parasitic effects due to mechanical stress σ and due to changes in the temperature T. In the method step 230 according to the present invention, the additional capacitances C_{Z1}(σ,T) and C_{Z2} (σ,T) are measured. This measurement can in principle be continuous. However, since mechanical stress generally does not change abruptly as already mentioned above, in many cases it will be sufficient to trigger the measurement of the additional capacitances as a test signal by means of a special trigger command from the ASIC side specifically at defined times, e.g. every time the sensor is started, at defined time intervals, when the temperature exceeds or falls below specific temperature points, or when defined events occur, for instance when starting an app on a smartphone or wearable device, in which a particularly high accuracy of the acceleration sensor (in particular a low offset and/or sensitivity error) is required.

The correlation factors V1(T), V2(T) previously ascertained on the ensemble can now be used to carry out a signal correction of the acceleration sensor signal (step 240) according to dC_{corr} (a, T)=dC (a, σ, T)−V1(T)*[C_{Z1} (σ, T)−C_{Z1} (σ=0, T)]−V2(T)*[C_{Z2} (σ, T)−C_{Z2} (σ=0, T)]. The acceleration sensor signal is thus largely freed of contributions caused by mechanical and thermomechanical stress, and the offset and sensitivity errors are correspondingly reduced. As mentioned above, it is in principle possible to also take into account higher terms, i.e. non-linear contributions in the correlation between the sensor signal and additional capacitances, in the signal correction.

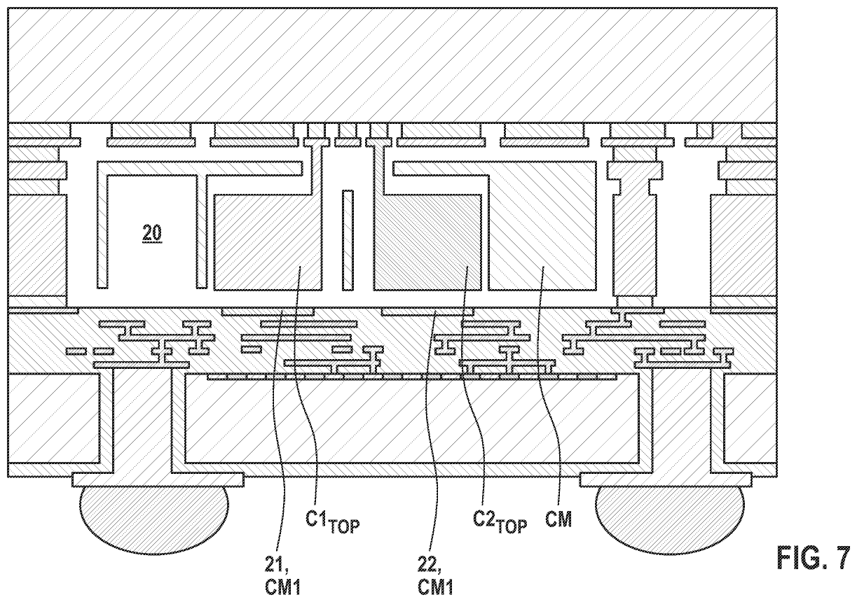

FIG. 7 shows a micromechanical sensor according to the present invention in a second embodiment example.

Depending on the position of the z-acceleration sensor within the chip and depending on the installation situation of the chip on a circuit board or in a chiplet, the additional capacitances C_{Z1} and C_{Z2} can behave very similarly or quite differently as the mechanical stress varies. If they behave very similarly, the separate evaluation of the two additional capacitances does not provide any significant additional information, and it can then be useful for the sake of the simplicity of the evaluation circuit and the correction procedure to set the two previously separate capacitive electrodes 21, 22 to a common potential CM1 and evaluate them together. The sum capacitance (C1_{TOP}+C2_{TOP})/CM1 is simply referred to hereinafter as C_{Z}.

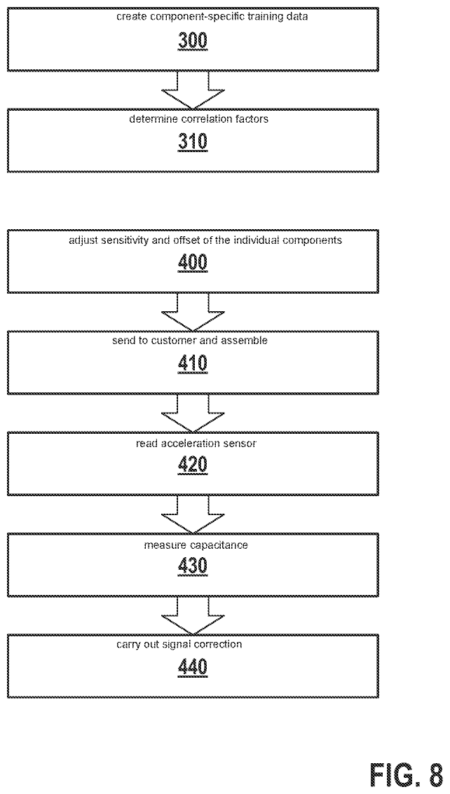

FIG. 8 shows a compensation method for correcting a signal for a micromechanical sensor according to FIG. 7.

The correction procedure corresponds largely to that of FIG. 5. Steps 300 and 310 correspond to steps 100 and 110. Steps 400, 410 and 420 correspond to steps 200, 210 and 220. Instead of the two additional capacitances C_{Z1}, C_{Z2}, however, only the one additional capacitance C_{Z} (σ, T) is taken into account in step 430. In step 440, a signal correction of the acceleration sensor signal is carried out according to

dC_{corr}(a,T)=dC(a,σ,T)−V(T)*[C_{z}(G,T)−C_{z}(σ=0,T)].

Of course, when creating the ensemble training data, not necessarily only the z-acceleration sensor data are measured, but other sensor data can be acquired at the same time as well, e.g. the x- and y-channel of a three-axis acceleration sensor and the three rotation rate sensor channels in an IMU (inertial measurement unit) in which a three-axis acceleration sensor is combined with a three-axis rotation rate sensor. If defined correlations between the other sensor channels and the additional capacitances are observed, these correlations can of course also be used to correct the signals of the other sensor channels.

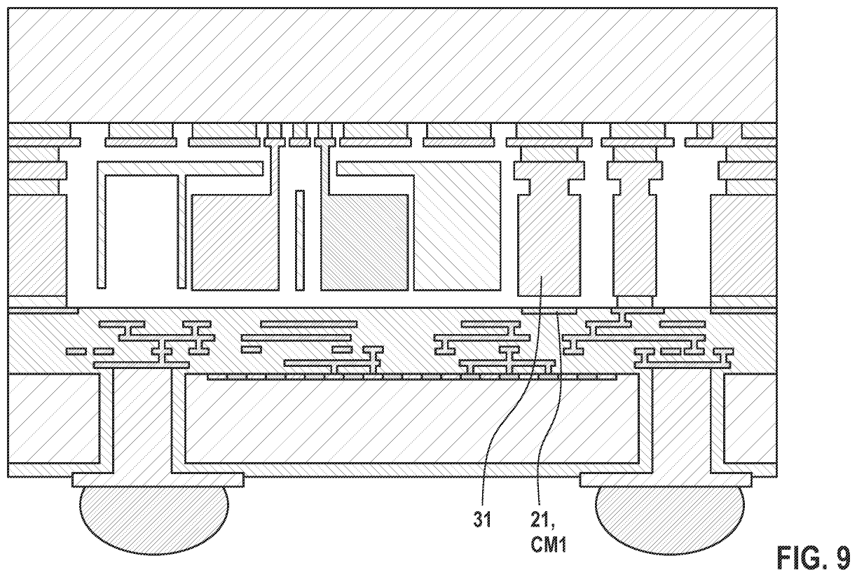

The arrangement of the additional electrodes above the top electrodes of a z-acceleration sensor as in the embodiment examples of FIGS. 4 and 7 should be considered particularly advantageous, because the available area is comparatively large and therefore a rather large additional capacitance can be formed. According to the present invention, however, it is in principle possible to dispose additional electrodes on the ASIC opposite to other not movable MEMS structures, such as mechanical anchoring blocks. As an example, FIG. 9 shows a micromechanical sensor according to the present invention in a third embodiment example.

In every case, only the capacitive electrode 21 and possibly the further capacitive electrode 22 are disposed on the cap substrate. All of the micromechanical structures, including the measuring electrodes, are disposed on the MEMS substrate. This is advantageous in that, in the arrangements according to the present invention of FIGS. 4, 7 and 9, the stress input into the ASIC takes place directly through the (not depicted) circuit board onto which the component is soldered, whereas the MEMS structures with their evaluation electrodes are positioned facing away from the circuit board. The stress input into the MEMS substrate, in particular at the evaluation electrodes, will consequently be comparatively reduced, but the additional capacitances between the ASIC and the MEMS will react relatively strongly to stress. The additional capacitances can therefore be used as a highly accurate stress sensor to precisely correct even comparatively small stress effects in the MEMS substrate. An arrangement with evaluation electrodes on the ASIC would in contrast be more affected by stress effects. Even with a highly accurate stress sensor, the residual errors after correction would be larger than for an arrangement with smaller initial errors at the evaluation electrodes.

In the described embodiment examples, the correlation factors are ascertained using training data ascertained on an ensemble of sensors. In principle, it is possible, albeit associated with significantly more effort in the adjustment, to also apply a mechanical stress stimulus to the component during the final test and adjustment procedure and to ascertain the correlation factors of the component individually and store them in the adjustment registers of the ASIC in order to achieve further improved stress compensation.

### LIST OF REFERENCE SIGNS

10 MEMS substrate
20 Cavity
21 Capacitive electrode
22 Further capacitive electrode
30 Micromechanical structure
31 Micromechanical structural element
32 Further micromechanical structural element
40 Cap substrate
51 Distance
52 Further distance
100 Oxide layer
300 Torsion spring
310 Torsion axis
410 Via
420 Redistribution layer
430 Solder bead

What is claimed is:

1. A micromechanical sensor, comprising:
a MEMS substrate;
a micromechanical structure disposed on the MEMS substrate, the micromechanical structure including at least one sensor electrode is disposed in a cavity;
a cap substrate disposed over the micromechanical structure and closing the cavity; and
a capacitive electrode disposed on an inner side of the cap structure, the capacitive electrode configured to produce a measuring capacitance with an adjacent micromechanical structural element on the MEMS substrate for measuring a distance between the capacitive electrode and the micromechanical structural element.

2. The micromechanical sensor according to claim 1, wherein the cap substrate is a semiconductor substrate which includes an integrated circuit.

3. The micromechanical sensor according to claim 1, wherein the micromechanical structural element is configured such that it cannot move.

4. The micromechanical sensor according to claim 1, further comprising:
a further capacitive electrode configured to produce a further measuring capacitance with a further adjacent micromechanical structural element for measuring a further distance between the further capacitive electrode and the further micromechanical structural element, the further capacitive electrode being disposed on the inner side of the cap substrate.

5. The micromechanical sensor according to claim 1, wherein micromechanical sensor is a z-acceleration sensor, wherein the adjacent micromechanical structural element is a fixed sensor electrode for measuring an acceleration.

6. A method for signal correction of a sensor signal of a micromechanical sensor including a MEMS substrate, on which a micromechanical structure including at least one sensor electrode is disposed in a cavity, and including a cap substrate, which is disposed over the micromechanical structure and closes the cavity, the method comprising the following steps:
correcting the sensor signal using a capacitive electrode which produces a measuring capacitance with an adjacent micromechanical structural element on the MEMS substrate for measuring a distance between the capacitive electrode and the micromechanical structural element and is disposed on an inner side of the cap substrate, the sensor signal being ascertained at least in part from a sensor capacitance between the sensor electrode and another part of the micromechanical structure.

7. The method for the signal correction of a sensor signal of a micromechanical sensor according to claim 6, wherein a correction contribution, which is formed from the measuring capacitance and at least one correlation factor, is subtracted from the sensor signal.

8. The method for the signal correction of a sensor signal of a micromechanical sensor according to claim 7, wherein the at least one correlation factor has a temperature dependence and the correction of the sensor signal is carried out as a function of temperature.

9. The method for the signal correction of a sensor signal of a micromechanical sensor according to claim 7, wherein the correction of the sensor signal also includes terms of at least second order of the measuring capacitance.

10. The method according to claim 6, wherein the measuring capacitance is used to correct the sensor signals of a plurality of sensor channels.
